(19) United States
(12) Patent Application Publication
(10) Pub. No.: US 2011/0260726 A1
(43) Pub. Date: Oct. 27, 2011

(54) PHASE LABELING USING SENSITIVITY ENCODING: DATA ACQUISITION AND IMAGE RECONSTRUCTION FOR GEOMETRIC DISTORTION CORRECTION IN EPI

(75) Inventors: Udomchai Techavipoo, Bangkok (TH); Thomas P. Leist, Wynnewood, PA (US); Song Lai, Cherry Hill, NJ (US)

(73) Assignee: THOMAS JEFFERSON UNIVERSITY, Philadelphia, PA (US)

(21) Appl. No.: 12/990,686

(22) PCT Filed: May 1, 2009
(86) PCT No.: PCT/US2009/042593

§ 371 Date: Jan. 18, 2011

Related U.S. Application Data
(60) Provisional application No. 61/050,552, filed on May 5, 2008.

(51) Int. Cl. G01R 33/565

(52) U.S. Cl. 324/309

(57) ABSTRACT

A phase labeling using sensitivity encoding system and method for correcting geometric distortion caused by magnetic field inhomogeneity in echo planar imaging (EPI) uses local phase shifts derived directly from the EPI measurement itself, without the need for extra field map scans or coil sensitivity maps. The system and method employs parallel imaging and k-space trajectory modification to produce multiple images from a single acquisition. The EPI measurement is also used to derive sensitivity maps for parallel imaging reconstruction. The derived phase shifts are retrospectively applied to the EPI measurement for correction of geometric distortion in the measurement itself.

### CROSS REFERENCE TO RELATED DOCUMENTS

The present application claims the benefit of priority of U.S. Provisional Patent Application Ser. No. 61/050,052 filed on May 2, 2008. The contents of the U.S. Provisional Patent Application are incorporated below by reference.

### FIELD OF THE INVENTION

The technical field generally relates to magnetic resonance imaging. More specifically, the invention relates to systems and methods for correcting geometric distortion in echo planar imaging (EPI) with phase labeling using sensitivity encoding.

### BACKGROUND OF THE INVENTION

Magnetic resonance imaging (MRI) uses a magnetic field and radio frequency (RF) energy pulses as a non-invasive method for analyzing objects. MRI is used extensively in medical imaging. In MRI, an object or patient is placed in an external magnetic field. The nuclear magnetic moments of the nuclei in the patient are excited at specific spin precession frequencies that are proportional to the external magnetic field. Radio frequency (RF) signals resulting from the precession of the spins are collected using receiver coils. The magnetic fields are altered using magnetic gradients, and the RF signals are collected that represent different anatomical regions of the patient. The collected signals are combined to produce a volumetric image of the nuclear spin density of the patient.

When imaging a patient or other object using MRI, the patient is placed in a constant external main magnetic field B₀. An additional magnetic field, in the form of radio frequency (RF) pulses, is applied orthogonally to the main magnetic field. The RF pulses have a unique frequency chosen to excite a particular nuclei, such as hydrogen, in the patient. The RF pulses excite the hydrogen nuclei, thereby increasing the energy state of the nuclei. After the RF pulse is turned off, the hydrogen nuclei relax and release RF energy as a free induction decay signal. The free induction decay signal can be transformed into an echo. The echoes are observed, measured, and converted into anatomical images. The RF pulses may have a wide frequency spectrum to excite nuclei over a large range of resonant frequencies. Similarly, the RF pulses may have a narrow frequency spectrum to excite nuclei over a more narrow range of resonant frequencies. Combined, or composite RF pulses appear as a series of RF pulses and may be used to excite nuclei over different ranges of resonant frequencies. Composite RF pulses may be transmitted to excite multiple ranges of resonant frequencies allowing for simultaneous collection of received signals from multiple areas of interest, such as multiple areas of the patient anatomy.

As hydrogen nuclei relax, the frequency that they give off is positively correlated with the strength of the magnetic field surrounding the nuclei. A magnetic field gradient along the z-axis is set up when an RF pulse is applied, and is shut off when the RF pulse is turned off. This “slice select” gradient causes the hydrogen nuclei at the high end of the gradient field, where the magnetic field is stronger, to precess at a high frequency (e.g., 42.6 MHz). Correspondingly, the nuclei at the low end of the gradient field precess at a lower frequency (e.g., 42.56 MHz). When a narrow RF pulse is applied, only those nuclei that precess at that particular frequency will be excited, and subsequently relax and release RF energy as a free induction decay signal. The nuclei “resonate” to that particular frequency. For example, if a magnetic gradient caused hydrogen nuclei to precess at rates from 42.56 MHz at the low end of the gradient to 42.6 MHz at the high end, and the gradient were set up such that the high end was located at the patient's forehead and the low end at the patient's chin, then a 42.56 MHz RF pulse would excite the hydrogen nuclei in a slice near the chin, and a 42.6 MHz pulse would excite the hydrogen nuclei in a slice near the forehead. When a single “slice” along the z-axis is selected, only the protons in that slice are excited by the specific RF pulse. The protons reach a higher energy level and subsequently relax to a lower energy level to give off energy as a radio frequency signal.

The second dimension of the planar patient image is derived using a phase-encoding gradient. As soon as the RF pulse is turned off, all of the nuclei in the activated higher energy level slice are in phase. A phase-encoding gradient is briefly applied in the y-direction in order to cause the magnetic vectors of nuclei along different portions of the gradient to have a different phase advance. The sequence of RF and gradient pulses is then repeated to collect all the data necessary to produce an image. As the pulse sequence is repeated, the magnitude of the phase-encoding gradient is stepped as the number of repetitions progresses. For example, the phase-encoding gradient may be evenly incremented after each repetition. The number of repetitions of the pulse sequence is dependent upon the type of image desired and can be any integer, such as 512, 1024, and the like. The polarity of the phase encoding gradient may also be reversed to collect additional RF signal data. For example, when the number of repetitions is 512, 256 of the repetitions may be positive, and the other 256 repetitions may have a negative polarity phase encoding gradient of the same magnitude.

When the RF pulse, slice select gradient, and phase-encode gradient are then turned off, a third magnetic field gradient along the x-axis is established. The x-axis gradient is the “frequency encoding gradient” or “read gradient.” This gradient causes the relaxing nuclei to precess at different rates, so that the nuclei near one end of the gradient begin to precess at one higher rate, and those at the other end of the gradient precess at an even higher rate. As these nuclei relax, the nuclei at the high end of the gradient give off the highest frequency RF signals. The read gradient is applied when the RF signals are to be measured. The second and third dimensions of the image are acquired using a fast Fourier transformation (FFT). The FFT decomposes the received RF signal into a sum of sine waves. Each of the sine waves have a different frequency, phases, and amplitudes. For example:

S(t)=a₀+a₁ sin(ω₁t+Φ₁)+a₂ sinω₂t+Φ₂)+ . . .

The amplitude of the received RF signal decays as the nuclei lose phase coherence and begin to cancel each other out according to:

$$A = {A}_{0} {e}^{\frac{- t}{{T}_{2}}}$$

where t is time, A0 is the initial amplitude of the received signal, and the

$${e}^{\frac{- t}{{T}_{2}}}$$

term is the decay constant that depends upon the uniformity of the main magnetic field, B₀. The fast Fourier transformation of the signal in the time domain can be represented in the equivalent frequency domain by a series of peaks of various amplitudes. In MRI, the signal is spatially encoded by changes of phase and frequency, which is then decomposed by performing a two-dimension Fourier transformation to identify pixel intensities across the image.

In the above example, the z-axis was used as the slice-select axis. However, either the x-axis or y-axis may be set up as the slice-select axis depending upon the desired image orientation and the anatomical structure of the patient to be examined. For example, when a patient is positioned in the main magnetic field, the x-axis may be utilized as the slice-select axis to acquire sagittal images, and the y-axis may be utilized as the slice-select axis to acquire coronal images.

Regardless of the orientation of the selected scan, mathematically, the slice select gradient, phase-encoding gradient, and read gradient are orthogonal. The result of the MRI scan in the frequency domain representation (k-space) is converted to image display in the time domain data after a 2D or 3D fast Fourier transformation (FFT). Generally, in a transverse slice, the read gradient is along the x-axis and the phase-encoding gradient is along the y-axis. In 3D MRI, an additional phase-encoding gradient is along z-axis to acquire data in a third dimension. When the number of phase-encoding steps is smaller than a binary number, the missing data in the k-space may be filled with zeros to complete the k-space so that an FFT algorithm may be applied.

The k-space is an array of numbers/data whose Fourier transform is the MRI image. In the frequency domain representation, the k-space data is arranged in an inhomogeneous distribution such that the data at the center of the k-space map contains low spatial frequency data. That is, the low spatial frequency data is the general spatial shape of the patient being scanned. The data at the edges of the k-space map contains high spatial frequency data including the spatial edges and details of the patient.

The more uniform the main magnetic field B₀, and the more uniform the frequency of the gradient fields and RF pulses, the higher the resulting image quality, because the precessing nuclei become de-phased more quickly when subjected to non-uniform magnetic fields. The main magnetic field, the gradient magnetic fields, and the frequency composition of the RF excitation pulses may all cause quicker de-phasing if any of these elements are non-uniform.

Echo-planar imaging (EPI) is a fast MRI data acquisition technique that has been widely used in many imaging applications for both structural and functional studies. Echo-planar imaging (EPI) techniques are capable of acquiring an entire MRI image in only a fraction of a second. However, EPI is sensitive to magnetic field inhomogeneity caused by imperfect magnetic field shimming and tissue susceptibility differences. Tissue susceptibility differences result from nuclei resonating at different frequencies depending upon the material in which the nuclei are located. Magnetic field inhomogeneity creates local magnetic field gradients superimposed on the applied spatial encoding gradients. Therefore, spatial locations are decoded incorrectly, resulting in geometric distortion. Specifically, magnetic field inhomogeneity causes magnetizations to spin at off-resonance frequencies. Consequently, the phases of the magnetizations after spatial encoding contain extra phases induced by the magnetic field inhomogeneity. These phase errors are linearly proportional to the resonance frequency offsets and the sampling intervals. Since EPI takes a relatively longer sampling interval to collect the data in the phase-encoding direction than conventional MRI imaging techniques, the geometric distortion in this direction is more pronounced than that in the frequency-encoding direction. For stereotactic or image-guided applications, geometric accuracy is crucial. In functional MRI (fMRI), diffusion tensor imaging (DTI), and DTI-based tractography, severely distorted images are difficult to register to anatomical images. Moreover, misplacement of the structures and local activations create incorrect fiber tracts and degrade the power of statistical comparisons of the fiber bundles (group analysis).

A number of distortion correction algorithms have been attempted previously. In general, conventional distortion correction techniques involve two steps, namely acquiring field inhomogeneity information and applying the field inhomogeneity information to correct the distortion. To obtain the field inhomogeneity information, single or multiple scans are performed with varying scan parameters, such as the echo time, the direction or polarity of the phase and frequency encoding gradients, the location of the k-space data, and the number of echoes or the number of encoding directions. The field inhomogeneity information may be represented in terms of field maps, phase shifts, amplitude and phase errors, point spread functions, or relationships between corrected and distorted coordinates. Some of the methods are neither practical because of their lengthy reference scans nor sufficiently robust to correct for high degrees of distortion. Moreover, field inhomogeneity information is generally derived from a given patient position in the magnet and is valid only for that particular patient position. Therefore, conventional scans for field inhomogeneity information have to be acquired immediately before or after the EPI measurements to reduce patient position inconsistencies. For lengthy or repeated EPI measurements, such as DTI, fMRI, or dynamic contrast agent studies, patient motion during or between the scans would invalidate the patient position consistency requirement for applying the field inhomogeneity information for geometric distortion correction. Further, it is also impractical to sacrifice the temporal resolution by inserting reference scans for obtaining field inhomogeneity information in between the dynamic points. For these reasons, EPI images in many applications are often used without geometric distortion correction.

Previous attempts to address geometric distortion correction have involved obtaining field maps from the EPI measurements for every dynamic time point. In one approach, field maps are directly estimated from k-space echo displacements of each individual region (or pixel) in the spatial domain. This method can be applied to gradient-echo and asymmetric spin-echo images, but not to symmetric spin-echo images. Further, it is computationally intensive because the echo displacements are estimated pixelwise. In another approach, the EPI trajectories are modified such that multiple low-resolution scans with different echo times are embedded within each dynamic point. For example, the center of the k-space is collected twice. Field maps obtained using this approach have a relatively lower spatial resolution.

In order to capitalize on the fast imaging times and diagnostic benefits afforded by echo planar imaging sequences, artifacts resulting from main B₀ magnetic field inhomogeneities and geometric distortion must be minimized. However, none of the previous EPI imaging sequences and techniques adequately correct geometric distortion while providing fast imaging times and high signal-to-noise measurements.

### SUMMARY OF THE INVENTION

The present invention provides a system, method, and computer program product for providing geometric distortion correction in echo planar imaging (EPI) that generates corrected images without the shortcomings of previous techniques. A system, method, and computer program product in accordance with the present invention employs phase labeling using sensitivity encoding (PLUS), that utilizes the EPI measurement data themselves to correct geometric distortion, without acquiring separate scans for field maps and coil sensitivity maps. The system and method of the present invention integrates the technique of phase labeling for additional coordinate encoding (PLACE) for mapping field inhomogeneity with the methods of simulated phase evolution rewinding (SPHERE) that applies the PLACE-derived field maps to correct the distortion. The PLACE technique requires at least two images to generate a field map. Instead of acquiring phase images with different echo times as in other techniques, in PLACE, the phase images are acquired with different pre-phase-encoding gradients. Without changing other parameters of the pulse sequence, PLACE varies the area of the pre-phase-encoding gradient by adding/subtracting an area equal to a multiple (N) of the area of a phase-encoding pulse (blip). This manipulation shifts the k-space data down/up N lines from the original k-space data. Field maps from PLACE possess the same distorted spatial domain as the distorted images and are easy to pass to the SPHERE calculations. SPHERE simulates the k-space data by re-phase-encoding each spatial location of a distorted image with additional reverse local phase error generated from a given field map. Finally, the simulated k-space data is inverse Fourier transformed to generate a corrected image with reduced artifacts and improved signal-to-noise ratios (SNRs).

The present invention employs phase labeling using sensitivity encoding (PLUS), that utilizes the EPI measurement data themselves to correct geometric distortion, without acquiring separate scans for field maps and coil sensitivity maps. The PLUS technique of the present invention incorporates a parallel imaging technique using phased array coils and their sensitivity maps to produce multiple images from a single measurement scan. The trajectories of k-space data are modified such that the phase differences of the images after parallel imaging reconstruction contain local phase shifts. These phase shifts are applied afterwards to correct the distortion in the average of the images reconstructed previously using parallel imaging. Ghosting artifacts are also removed by alternately assigning k-space lines with the same readout directions into groups before applying parallel imaging reconstruction. The measurement data themselves are also used to derive sensitivity maps for parallel imaging.

These and other advantages, aspects, and features of the present invention will become more apparent from the following detailed description of embodiments and implementations of the present invention when viewed in conjunction with the accompanying drawings. The present invention is also capable of other embodiments and different embodiments, and details can be modified in various respects without departing from the spirit and scope of the present invention. Accordingly, the drawings and descriptions below are to be regarded as illustrative in nature, and not as restrictive.

### BRIEF DESCRIPTION OF THE DRAWINGS

The accompanying drawings illustrate an embodiment of the invention and depict the above-mentioned and other features of this invention and the manner of attaining them. In the drawings:

FIG. 1A illustrates a modified EPI trajectory for PLUS.

FIG. 1B illustrates the pulse sequence diagram for the EPI trajectory of FIG. 1A.

FIGS. 1C-1F show k-space data rearranged into four groups according to EPI trajectories.

FIG. 2 shows a block diagram illustration of a phase labeling using sensitivity encoding system in accordance with the present invention.

FIGS. 3A-3B show a comparison of artifacts in gradient-echo images acquired with a modified EPI trajectory and with a conventional EPI trajectory.

FIGS. 4A-4F illustrate the generation of a coil sensitivity map in accordance with the present invention.

FIGS. 5A-5D shows averaged unfolded images from a PLUS EPI trajectory and a conventional EPI trajectory.

FIGS. 6A-6F show a comparison of phase-shift maps estimated using PLUS and phase-shift maps estimated using PLACE, and the difference between the two phase-shift maps.

FIGS. 7A-7D show a comparison of average unfolded images and the geometric distortion correction using the phase-shift maps using PLUS and geometric distortion correction using the phase-shift maps using PLACE.

FIGS. 8A-8D show the geometric distortion correction results of conventional EPI images using the phase-shift maps from PLUS and from PLACE.

FIGS. 9A-9D show 128-shot conventional gradient-echo images and T1-weighted MP-RAGE images.

FIGS. 10A-10B illustrate two EPI trajectories for PLUS.

FIG. 11 illustrate an MRI system in accordance with the present invention.

### DETAILED DESCRIPTION OF THE INVENTION

The following detailed description of the invention refers to the accompanying drawings and to certain preferred embodiments, but the detailed description does not limit the invention. The scope of the invention is defined by the appended claims and equivalents as it will be apparent to those of skill in the art that various features, variations, and modifications can be included or excluded based upon the requirements of a particular use.

As illustrated in the discussion below, the present invention includes a system, method, and computer program product for providing geometric distortion correction in echo planar imaging (EPI) that generates corrected images without the shortcomings of previous techniques. A system, method, and computer program product in accordance with the present invention employs phase labeling using sensitivity encoding (PLUS), that utilizes the EPI measurement data themselves to correct geometric distortion, without acquiring separate scans for field maps and coil sensitivity maps. The system and method of the present invention integrates the technique of phase labeling for additional coordinate encoding (PLACE) for mapping field inhomogeneity with the methods of simulated phase evolution rewinding (SPHERE) that applies the PLACE-derived field maps to correct the distortion. The system, method, and computer program product of the present invention corrects geometric distortion caused by magnetic field inhomogeneity in echo planar imaging (EPI) by using local phase shifts derived directly from the EPI measurement itself, without the need for extra field map scans or coil sensitivity maps.

Phase Labeling Using Sensitivity Encoding (PLUS) Process

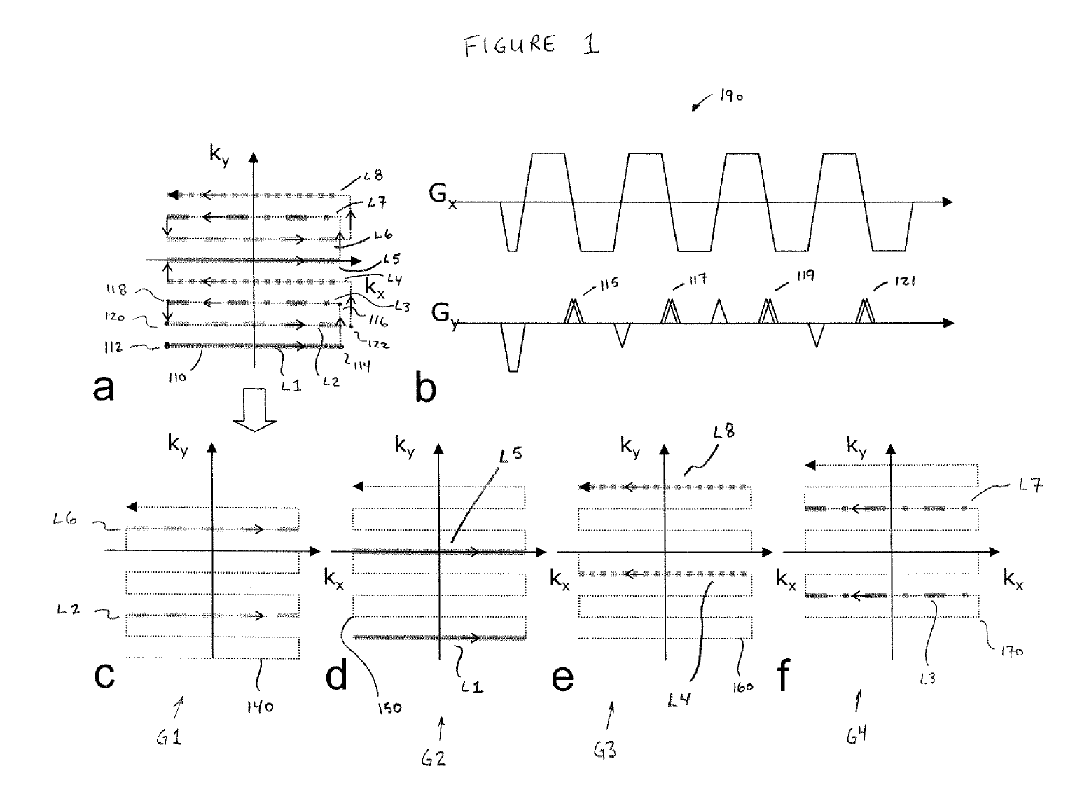

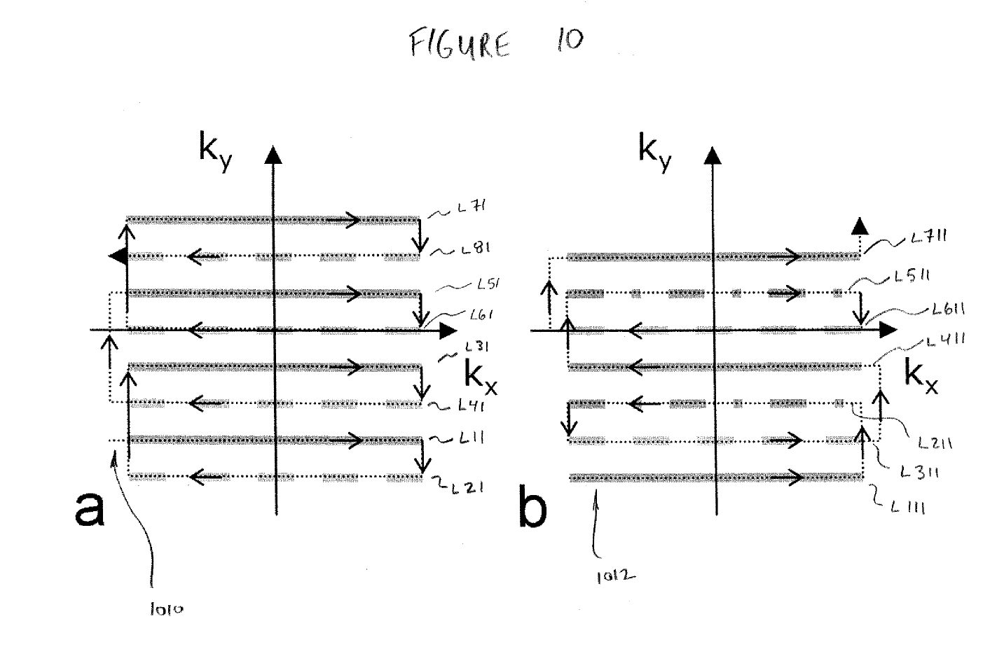

To create a field map, phase labeling for additional coordinate encoding (PLACE) requires extra scans that have different pre-phase-encoding areas compared to the EPI measurement scan. In order to combine these separate scans into one single scan, phase labeling using sensitivity encoding (PLUS) techniques in accordance with the present invention skips lines in each of the k-space data sets and acquires the remaining lines in a time multiplexed fashion, resulting in a new k-space trajectory. The k-space trajectory for PLUS shown in FIG. 1A may be modified in a number of ways. One example is, where k-space lines may be rearranged into two and three groups, respectively. Additional example trajectories are shown in FIG. 10 and in the accompanying discussion to FIG. 10.

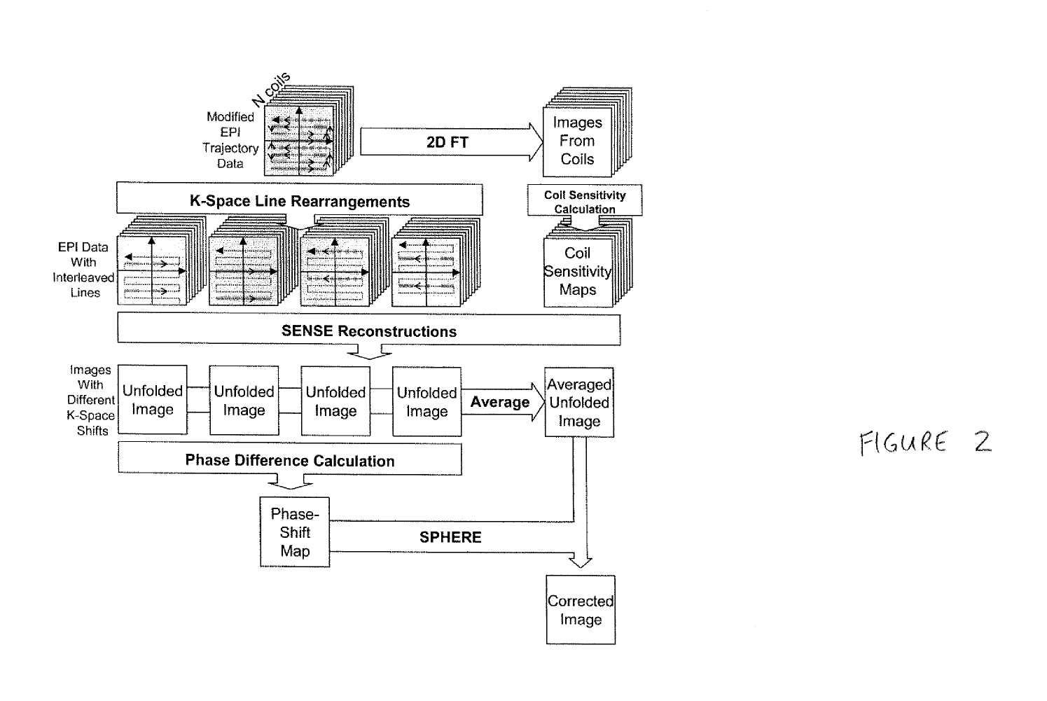

Returning to FIG. 1, a PLUS trajectory (shown in FIG. 1A as thin dotted lines, for example reference numeral 110) and its pulse sequence diagram 190 are presented in FIG. 1A and FIG. 1B, respectively. For every four lines of the PLUS trajectory 110, the acquisition order of the second and the third lines of the k-space data are switched. For example, starting at PLUS trajectory acquisition starting point 112 and moving in the positive kₓ direction, for every four lines of the PLUS trajectory, the acquisition order of the second and third lines are switched. This may be illustrated by starting at PLUS trajectory acquisition starting point 112 and moving along the PLUS trajectory 110 through acquisition points 114, 116, 118, 120, 122. Some of the pulses (blips) shown in FIG. 1B are doubled as represented by double triangles 115, 117, 119, 121. The k-space data shown in FIG. 1A are then rearranged into four group G1, G2, G3, G4 by alternately assigning a k-space line to a group. That is, the thick lines (solid L1, L5, dash-dash L2, L6, dash-dot L3, L7, and dotted lines L4, L8) represent lines of the k-space data in FIG. 1A and their assignments to groups G1, G2, G3, G4. The four EPI trajectories shown as thin dotted lines 140, 150, 160, 170 presented in FIGS. 1C-1F are equivalent to the trajectories used in PLACE that have −1, 0, 0, and +1 additional pulses (blips), respectively, in the pre-phase gradients. The missing k-space lines in each group G1, G2, G3, G4 will be filled up using parallel imaging reconstruction as described below. This reconstruction is equivalent to unfolding the images in the spatial domain. After the reconstruction, the phase differences between the unfolded images from FIGS. 1C and 1D and from FIGS. 1E and 1F are calculated and then averaged to obtain a phase-shift map. Finally, the simulated phase evolution rewinding (SPHERE) process is applied to the average of the unfolded images obtained from the previous step. A block diagram of the steps in carrying out the PLUS method in accordance with the present invention is shown in FIG. 2.

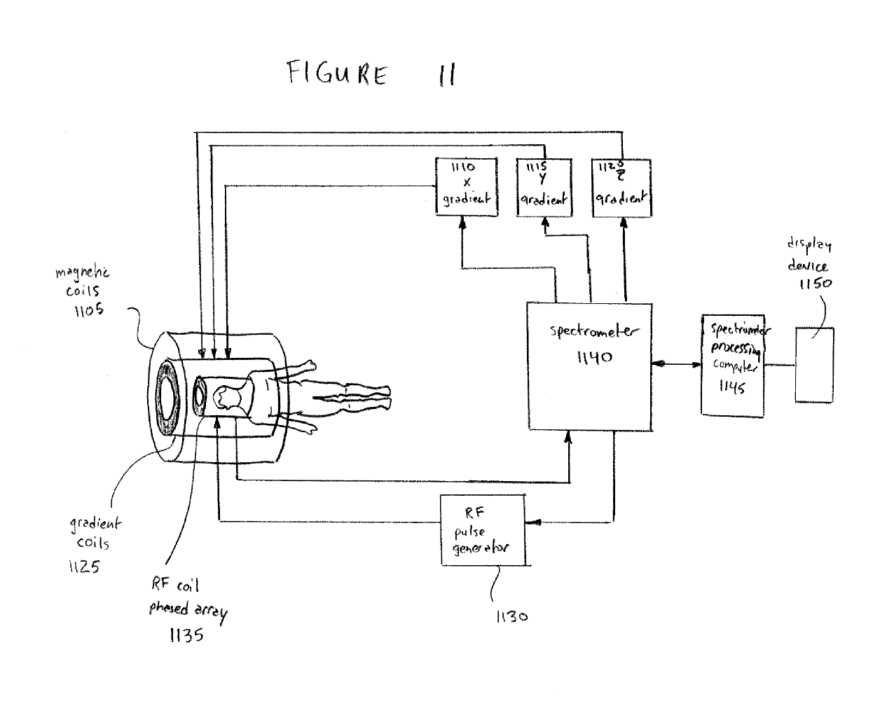

FIG. 11 illustrates a magnetic resonance imaging (MRI) system in accordance with the present invention configured to carry out the PLUS method. The MRI system includes magnetic coils 1105 that provide a constant main magnetic field. The main magnetic field strength may be 0.5 Tesla, 1 Tesla, 1.5 Tesla, 2 Tesla, and the like. Magnetic gradients are generated by gradient amplifiers, including the x-gradient 1110, y-gradient 1115, and z-gradient 1120. The x-gradient 1110, y-gradient 1115, and z-gradient 1120 produce waveforms that modify the main magnetic field by generating gradient magnetic fields through gradient coils 1125. A radio frequency (RF) pulse generator 1130 creates RF pulses and transmits the pulses using RF coil 1135. The transmitted pulses excite the nuclei of the patient or object being examined. Phased array coil 1135 may also receive the relaxation RF signals from the nuclei in the object as the excited nuclei precess. As outlined further, the nuclei may be hydrogen nuclei, or other atoms. A spectrometer 1140 processes the received RF emission signals from the nuclei and further processes the received signals using the PLUS techniques of the present invention. The images may be further processed using computer system 1145, and the images or imaging information may be displayed on a display device 1150.

### Parallel Imaging Reconstruction

The sensitivity encoding (SENSE) process is used for parallel imaging reconstruction in accordance with the present invention. Other parallel imaging algorithms may be applied as well. The SENSE reconstruction performs essentially two steps, namely calculating coil sensitivity maps and applying the maps to unfold images. In accordance with the present invention, the SENSE reconstruction process is modified so that phases of unfolded images contain additional phases of a coil sensitivity map. These additional phases will be canceled out when calculating a phase-shift map. Further, the modified SENSE reconstruction processes described are independent from the MRI scanner internal image reconstruction software and the coil sensitivity maps are calculated directly from the measurement data.

### 1) Coil Sensitivity Generation

As outlined above, to perform the parallel imaging reconstruction using the modified SENSE reconstruction process in accordance with the present invention, a coil sensitivity map is calculated, and then the map is applied to unfold the images. To calculate the coil sensitivity map, for the k^{th} coil, the complex-valued reference image sₖ is given by:

sₖ=ρcₖ+nₖ=|ρ∥cₖ|e^{ƒ(α+β}^{ₖ}⁾+nₖ, Equation [1]

where ρ and cₖ are the complex-valued images of the object and the k^{th} coil sensitivity, respectively; α and β are their phases, respectively; nₖ is the zero-mean, complex-valued white noise from the k^{th} coil. Assuming that the magnitude of the object is equal to the square root of the sum of the squares (SOS), which is:

$$\vert ρ \vert = \sqrt{{\sum }_{k = 1}^{K} {\vert {s}_{k} \vert}^{2}} , \qquad Equation [ 2 ]$$

where K is the number of coils in the phased array coil. By dividing Equation [1] by the value from Equation [2], the object magnitude modulation from the signal may be eliminated. That is:

s′ₖ=|cₖ|e^{j(α+β}^{ₖ}⁾+n′ₖ, Equation [3]

where the primes denote the modifications of the measurement and noise. The |cₖ| can be estimated by masking the object region and fitting the image with a two-dimensional polynomial. For example, in accordance with the present invention, the order of the polynomial may be the 5^{th} order. To obtain the coil sensitivity phases, the object phases a have to be removed from Equation [3] as well. Instead of obtaining the true coil sensitivity phases, in accordance with the present invention, the phase differences between the images from the N^{th} coil and from the other coils may be utilized. By multiplying Equation [3] with the complex conjugate image from the N^{th} coil, the object phases a may be removed and images containing phase differences βₖ−β_{N} may be created as follows:

s″ₖ=|cₖ∥c_{N}|e^{j(β}^{ₖ}^{-β}^{_{N}}⁾+n″ₖ, Equation [4]

where the double primes denote the modifications of the measurement and the noise. Without the object phases, the phases of the image in Equation [4] are smooth. The phase differences βₖ−β_{N} can be estimated by low-pass filtering the image in Equation [4] and calculating the image phases. An alternative approach is to find the phase differences from Equation [1], instead of Equation [3]. This approach can avoid the noise amplification from dividing the measurements with the sum of the squares (SOS) image.

### 2) Image Unfolding

Once the coil sensitivity map is calculated, the coil sensitivity map may be used to unfold the images. For example, the equation for a folded image is as follows.

$${f}_{k} ( {y}^{′} ) = {\sum }_{i = 1}^{M} {c}_{k} ( {y}_{i} ) u ( {y}_{i} ) , \qquad Equation [ 5 ]$$

where ƒₖ(y′) is a complex pixel value at y′ of a folded image from the k^{th} coil; u(yᵢ) is a complex pixel value at yᵢ of the unfolded image. The index i denotes the fold and M is the total number of folds. Note that the x coordinate is omitted. By defining dₖ=cₖc_{N}*=|cₖ∥c_{N} | exp(j(βₖ−β_{N})), which is estimated from the first step in Equation [4], where * is a complex conjugate operation, Equation [5] may be rewritten as:

$${f}_{k} ( {y}^{′} ) = {\sum }_{i = 1}^{M} {d}_{k} ( {y}_{i} ) v ( {y}_{i} ) , \qquad Equation [ 6 ]$$

where v=u/c_{N}*=(|u|/c_{N}|)exp(j(θ+β_{N})), where θ is the phase of the unfolded image u. The number of folds has to be less than the number of coils so that v can be estimated. The method of the present invention estimates v using least squares. The magnitude of the unfolded image |u| can be found by multiplying the magnitude of the result |v| with a known |c_{N}| from the previous step. However, the phase of the result is θ+β_{N}, where β_{N} is unknown. Since only the phase shifts between the two unfolded images are needed, the common term β_{N} will be eliminated in the phase-shift map calculation.

### Phase-Shift Maps

As in phase labeling for additional coordinate encoding (PLACE), a phase-shift map ΔΦ in accordance with the present invention may be calculated from two images that have different additional blip areas in the pre-phase-encoding gradients. That is:

$$Δφ = \frac{1}{i - j} Arg ( R P R ( {I}_{i} ) R P {R ( {I}_{j} )}^{*} ) , \qquad Equation [ 7 ]$$

where Arg(.) represents the phase angles of a complex-valued image; RPR(.) is an operation to remove a phase ramp in the phase-encoding direction (or the y-direction) of the image that is created by adding blips to the k-space data; the indices i and j denote the numbers of blips added to the k-space data. The relationship between this phase-shift map and the field map ΔB₀ is given by:

ΔΦ=γΔB₀T, Equation [8]

where γ is the gyromagnetic ratio and T is the k_{y} sampling interval. The phase ramp is equal to 2πny/N_{y}, where n is the number of additional blips and N_{y} is the number of pixels in the y-direction. The phase ramp may be removed using circular shifts in the k_{y} direction.

According to the PLUS trajectory in accordance with the present invention, four images are generated after the modified SENSE reconstruction. Let u₁ to u₄ represent these unfolded images from k-space data in FIGS. 1C-1F, respectively. The images u₁ to u₄ contain −1, 0, 0, and +1 additional blips, respectively. A phase-shift map in accordance with the present invention can be calculated by:

ΔΦ=Arg((RPR(u₁)RPR(u₂)*+RPR(u₃)RPR(u₄)*)/2). Equation [9]

Instead of averaging the phases of the image products, this method in accordance with the present invention enhances the accuracy of the estimation because of its self-weighting scheme, and no phase unwrapping is needed. Further, each image pair in the image products of this equation is derived from the k-space data in which the lines are scanned in the same direction. For example, the k-space lines of the images u₁ and u₂ are scanned from left to right, while those of the images u₃ and u₄ are scanned from right to left. Therefore, the phases accumulated along the readout direction are canceled out.

### Distortion Correction

Simulated phase evolution rewinding (SPHERE) is used to apply a phase-shift map to correct a distorted image. The distorted image has to be upsampled before applying SPHERE in order to avoid k-space aliasing artifacts caused by scaling the spatial domain. With the system and method of the present invention, upsampling to four times is sufficient to avoid k-space aliasing artifacts. Of course, higher upsampling may also be employed. Assuming that w is a distorted image that is upsampled to R times the number of the original pixels in both x and y directions, a x-k_{y} space data h after rewinding the phase error using a phase-shift map ΔΦ is given by:

$$h ( p , n ) = \frac{1}{{RN}_{y}} {\sum }_{q = - {RN}_{y} / 2}^{{RN}_{y} / 2} w ( p , q ) {e}^{- j n Δφ ( p , q )} {e}^{j 2 π nq / {RN}_{y}} , \qquad Equation [ 10 ]$$

where n is an index for the k_{y} direction; p and q are indices of the x and y directions, respectively; and N_{y} is the total number of the original pixels in the y direction. The components of h(p, n) where q<−(R−1)N_{y}/2 and q>(R−1)N_{y}/2 are removed afterwards to prevent k-space aliasing. Finally, inverse Fourier transformation is applied in the k_{y} direction and downsampling is applied to reduce the number of pixels to match the original matrix size.

### DATA ACQUISITION AND PLUS PROCESS EXAMPLE

A method of acquiring data and images in accordance with the present invention may be performed using a 3 Tesla MRI scanner with an eight-channel sensitivity encoding (SENSE) head coil to receive imaging signals from the object under study. The head coil may employ a phased array configuration of coils. A pulse sequence was developed and used to acquire k-space data for phase labeling using sensitivity encoding (PLUS) as illustrated in FIG. 1B. As shown in FIG. 1B, the phase encoding gradient pulse (blip) area is doubled at some of the phase encoding points 115, 117, 119, 121 as indicated by double triangles. The k-space data is then rearranged into four groups G1, G2, G3, G4. The four groups G1, G2, G3, G4 represent data in common EPI trajectories 140, 150, 160, 170 with different numbers of additional blips added to the pre-phase encoding gradients. For example, in FIGS. 1C-1F, the numbers of additional blips are −1, 0, 0, and 1, respectively. As shown in FIGS. 1C-1F, in each group G1, G2, G3, G4, k-space lines are traversing in the same readout direction. The modified EPI trajectory was based on a general gradient echo EPI sequence for fMRI studies.

The pulse sequence 190 used to acquire k-space data for phase labeling using sensitivity encoding (PLUS) may include the following scan parameters. TR may be set to 2500 ms, and TE set to 35 ms. The FOV was 384 mm with 3×3 mm2 in-plane resolution for an imaging phantom and was 410 mm with 3.2×3.2 mm2 in-plane resolution for a human brain. Slice thickness was 4 mm. The magnitude and phase images were recorded from the individual coils of the eight-channel sensitivity encoding (SENSE) head coil. Additional imaging sequences were also performed for comparison purposes, including common gradient-echo EPI data (without k-space trajectory modification), gradient-echo data using PLACE (5 dynamics with ±2 additional blips in pre-phase-encoding gradients), 128-shot conventional gradient-echo data (without using EPI readout), and high resolution T1-weighted images using an MP-RAGE sequence. Post acquisition processing was performed on the acquired signal data.

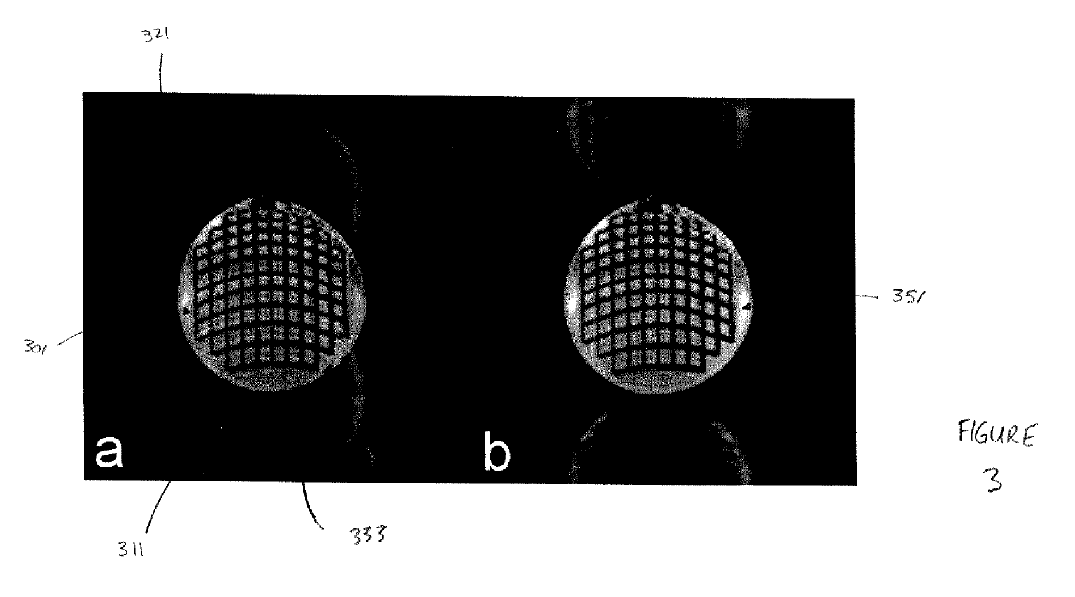

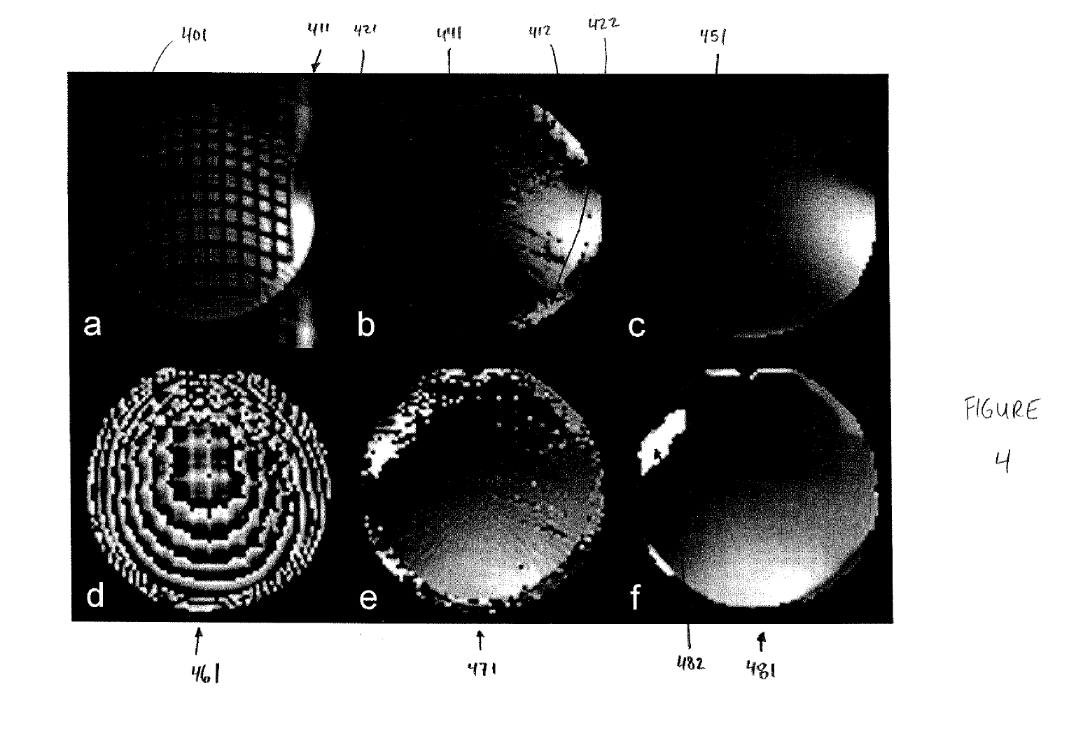

FIG. 3 is a comparison of artifacts in the gradient-echo images acquired with the modified EPI trajectory for the PLUS image 301 in FIG. 3A) and with a conventional EPI trajectory 351 in FIG. 3B. These images 301, 351 are the square roots of the sums of the squares of the images from the multi-channel phased array coils used to receive the imaging signals from the object (imaging phantom) under study. The image from each coil is reconstructed using a 2D Fourier transformation. As shown in FIG. 3A, the PLUS trajectory creates additional ghosting artifacts 311, 321 at ±N/4 pixels (where N is the number of pixels in phase-encoding direction and the origin is at the center of the image 301). There are significant interferences from ghosts, especially at the lower right corner 333 of the imaging phantom. This is caused by the k-space phase discontinuity from switching the acquisition orders of the third and the fourth lines for every four lines of the trajectory. These N/4 ghosts have a small effect on the calculations of the phase labeling using sensitivity encoding (PLUS) process. The effect is further demonstrated in FIGS. 4A-4F. Eddy current effects were automatically compensated by a calibration mechanism in the MRI scanner. As shown in FIGS. 3A-3B, eddy-current distortion is unnoticeable in the images 301, 351.

FIGS. 4A-4F demonstrate the generation of a coil sensitivity map. An individual image 401 from one coil of the phased array is shown in FIG. 4A. The upper and lower right parts 411, 421 of the object in FIG. 4A are affected by the interference of the N/4 ghosts. The individual image 401 from the phased array coil is divided by the square roots of the sums of the squares image 301 in FIG. 3A, and the resulting raw sensitivity magnitude image 441 is shown in FIG. 4B. After the division operation is performed, the magnitudes of the quotient show some remaining interference patterns 412, 422 as seen in FIG. 4B. However, these patterns 412, 422 disappear after polynomial fitting as shown in the image 451 in FIG. 4C. The phases of the quotient evolve rapidly as shown in the image 461 in FIG. 4D. In contrast, the phase differences between the combined images from two coils of the phased array evolve slower as shown in image 471 in FIG. 4E, and they become very smooth after low-pass filtering as shown in image 481 in FIG. 4F. The discontinuity of the shades of colors at the upper left parts 482 of the phantom is caused by phase wraparound. This discontinuity does not affect the parallel imaging reconstruction performed in accordance with the present invention.

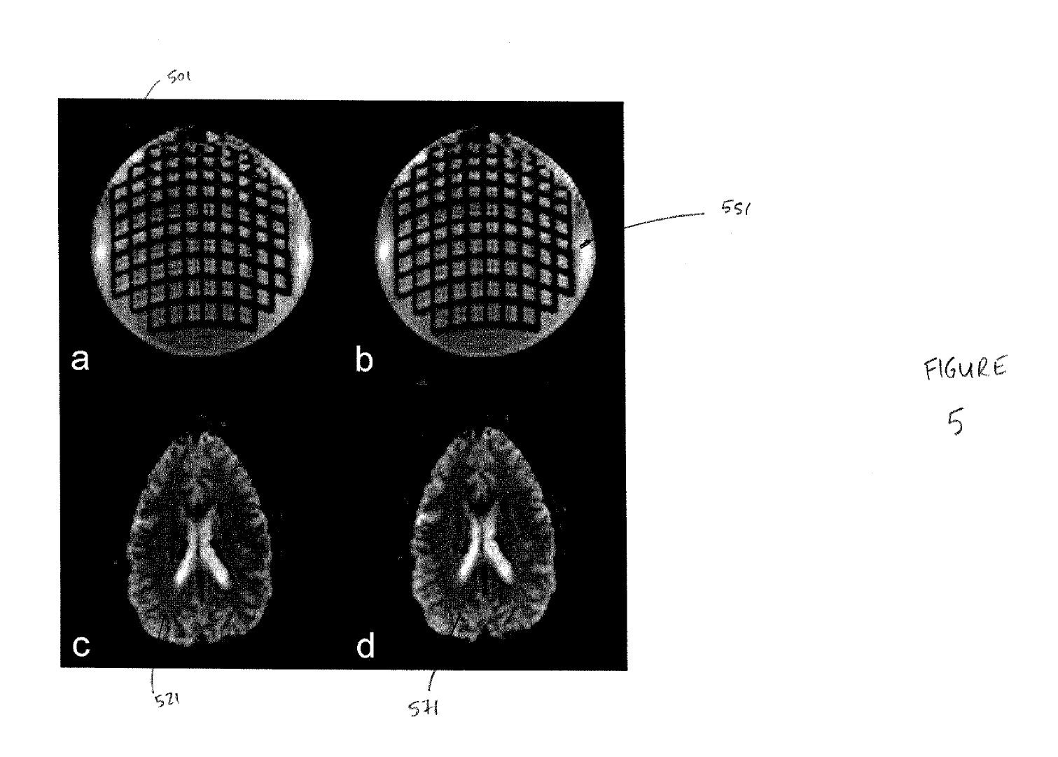

Averaged unfolded images and regular EPI images of a phantom and a brain are shown in FIG. 5. The phantom image 501 in FIG. 5A is generated from the same k-space data used in FIG. 3A but includes the PLUS method described above. The ghosting artifacts and their interferences exhibited in FIG. 3 completely disappear. This averaged unfolded image 501 in FIG. 5A is comparable with the conventional EPI image shown in FIG. 5B. The same comparison is shown for the brain images 521, 571 in FIGS. 5C and 5D.

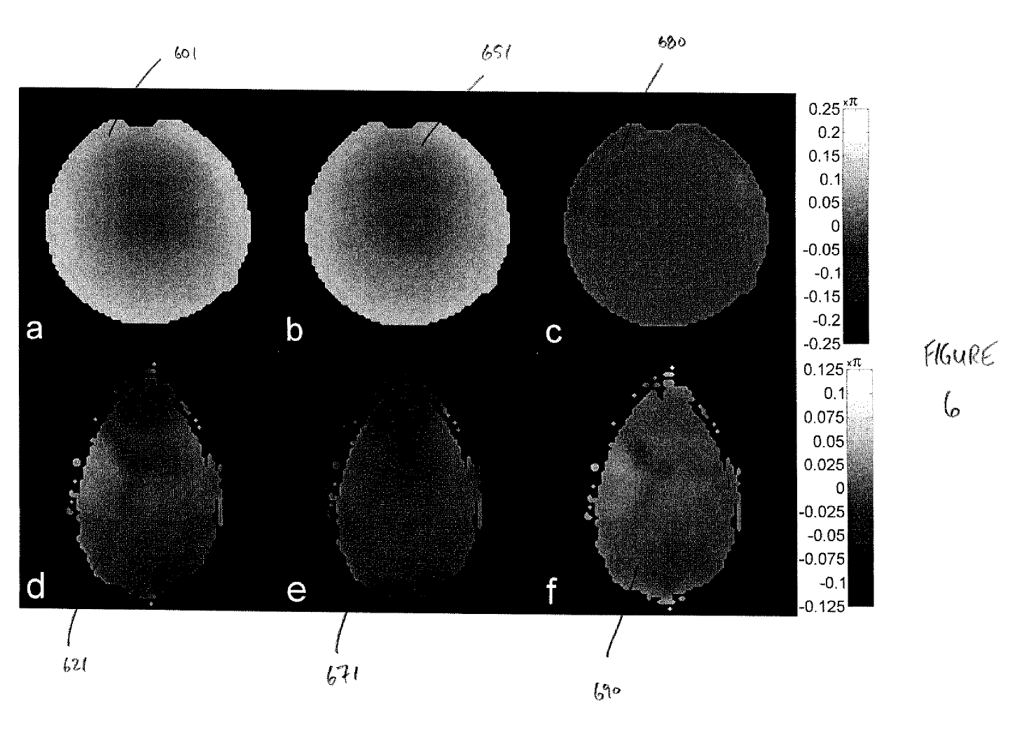

Phase-shift maps for the phantom and brain images 501, 521, 551, 571 in FIG. 5 are shown in FIG. 6. The maps 601, 621 estimated using PLUS are shown in FIGS. 6A and 6D and the maps 651, 671 estimated using PLACE are shown in FIGS. 6B and 6E. The differences 680, 690 between the maps are also shown in FIGS. 6C and 6F. As can be seen from FIGS. 6C and 6F, the field inhomogeneity in the phantom is more pronounced than the field inhomogeneity in the brain for this particular slice. For example, the range of the colorbar shades is ±π/4 for the phantom images 601, 651 and ±π/8 for the brain images 621, 671. In general, phase-shift maps estimated using PLUS are slightly different from those estimated using PLACE. The differences between the two estimations are small. For example, the mean and the standard deviation are −2.94×10⁻³±5.69×10⁻³π radian (−0.19±0.36 pixels) for the phantom and are 7.19×10⁻³±7.33×10⁻³π radian (0.46±0.47 pixels) for the brain.

The phase-shift maps may be evaluated by applying them to correct the geometric distortion in the images in FIG. 5 using a simulated phase evolution rewinding (SPHERE) algorithm. This evaluation of the phase-shift maps may be compared using the following image correction techniques.

(1) PLUS Correction to Unfolded Images

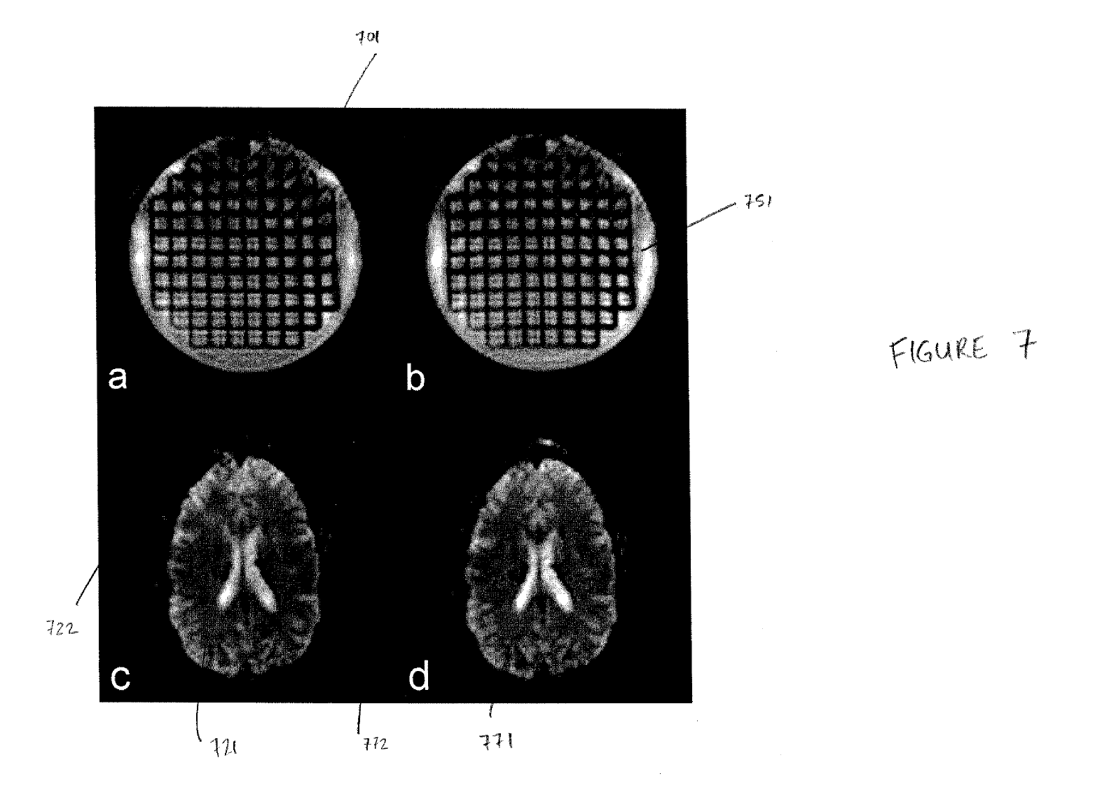

The phase-shift maps 601, 621 from PLUS in FIGS. 6A and 6D are applied to the averaged unfolded images 501, 521 in FIGS. 5A and 5C. The corrected images 701, 721 are shown in FIGS. 7A and 7C. These images 701, 721 are typical images resulting by performing the PLUS method on the averaged unfolded images in accordance with the present invention. Results in the other categories below are shown for comparison purposes.

(2) PLACE Correction to Unfolded Images

The phase-shift maps 651, 671 from PLACE in FIGS. 6B and 6E are applied to the averaged unfolded images 501, 521 in FIGS. 5A and 5C. The corrected images 751, 771 are shown in FIGS. 7B and 7D.

(3) PLUS Correction to Conventional EPI Trajectory Images

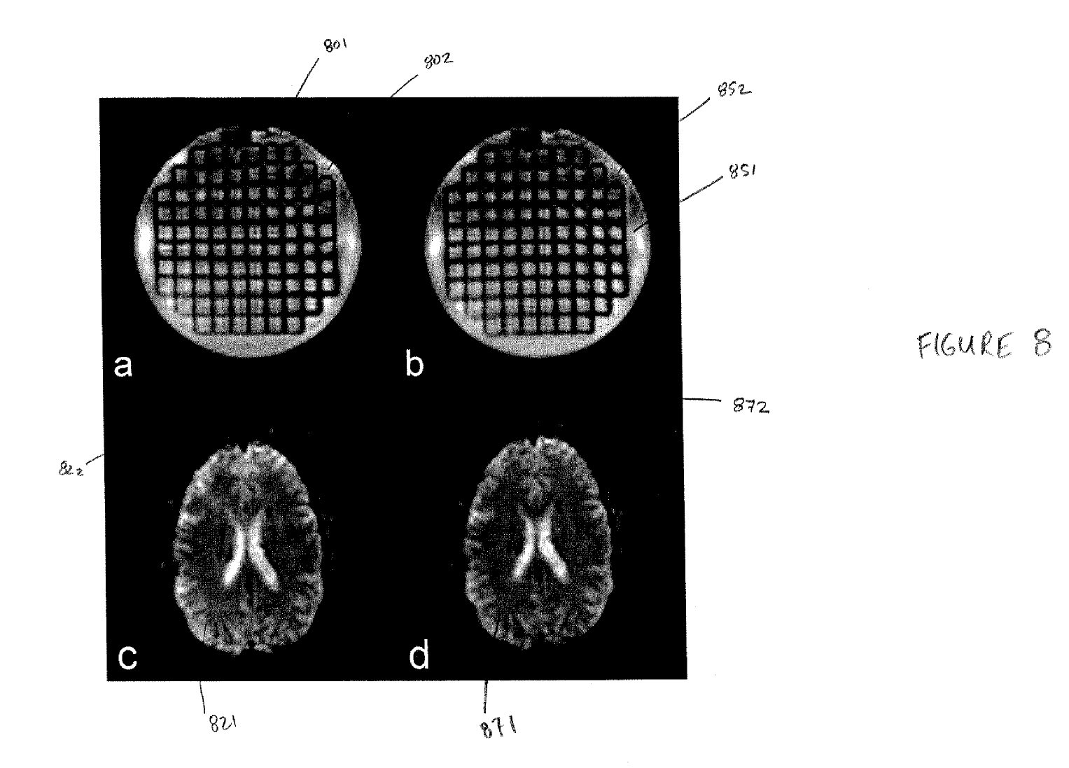

The phase-shift maps 601, 621 from PLUS in FIGS. 6A and 6D are applied to the regular EPI images 551, 571 in FIGS. 5B and 5D. The corrected images 801, 821 are shown in FIGS. 8A and 8C.

(4) PLACE Correction to Conventional EPI Trajectory Images

Finally, the phase-shift maps 651, 671 from PLACE in FIGS. 6B and 6E are applied to the regular EPI images 551, 571 in FIGS. 5B and 5D. The corrected images 851, 871 are shown in FIGS. 8B and 8D. These images 851, 871 are typical images resulting by performing the PLACE method in concert with the SPHERE correction.

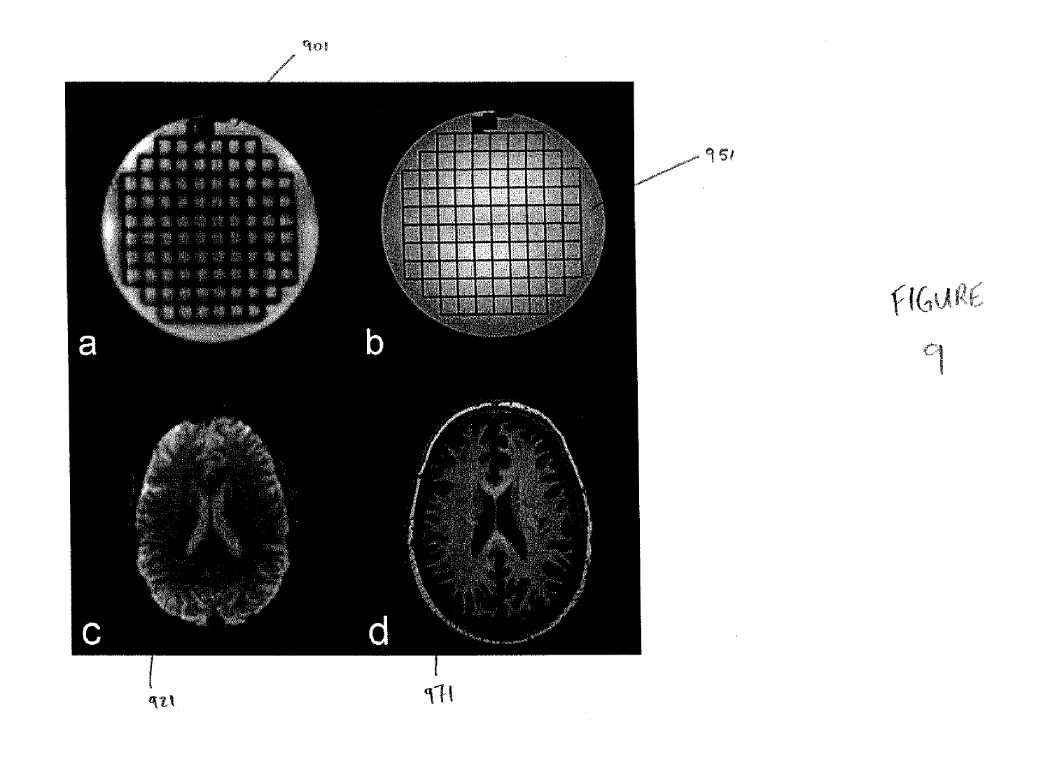

The above images may also be compared to other types of reference images. For example, in FIG. 9A a 128-shot conventional gradient echo image 901 of a phantom is shown, and in FIG. 9C, a 128-shot conventional gradient echo image 921 of a brain is shown. Similarly, in FIG. 9B, a T1-weighted MP-RAGE image 951 of a phantom is shown, and in FIG. 9D, a T1-weighted MP-RAGE image 971 of a brain is shown.

The corrected images 701, 751 in FIGS. 7A and 7B are comparable. That is, the correction afforded by the PLUS techniques of the present invention compared to the PLACE techniques. For phantom images 701, 751 in FIGS. 7A and 7B, the distorted geometry of the checkerboard inside the phantom is corrected, and the correction is comparable to the reference images 901, 951 in FIGS. 9A and 9B. In the phantom images 701, 751 the upper half of the checkerboard appears noisier than the lower half. The corrected brain images 721, 771 in FIGS. 7C and 7D are very comparable, with the exception of a faint skull structure 772 in FIG. 7D that appears more contiguous than that of the corresponding skull structure 722 shown in FIG. 7C.

The corrected images 801, 851 in FIG. 8 are also very similar and resemble the reference images 901, 951 in FIG. 9. The upper right corner 802 of the checkerboard in FIG. 8A is slightly distorted compared to the upper right corner 852 in FIG. 8B. The brain images 821, 871 in FIGS. 8C and 8D are almost indistinguishable, except for a small part of the skull structure at the top of the image 871 in FIG. 8D that has slightly improved image quality than the image 821 in FIG. 8C. A small area in the right hemisphere, anterior to the corpus callosum, in FIG. 8C is also slightly brighter than the corresponding structure in FIG. 8D.

Even though distorted phantom images from averaged unfolded image 501 in FIG. 5A and from regular EPI image 551 in FIG. 5B are comparable initially, the results after applying the same phase-shift maps are noticeably different. As can be seen by comparing the images 701, 801 in FIGS. 7A and 8A, respectively, or the images 751, 851 in FIGS. 7B and 8B, respectively, the images 801, 851 in FIGS. 8A and 8B show improved image quality. For example, the upper half of the checkerboard in FIGS. 8A and 8B is clearer. Also, the shape of the squares inside the checkerboard in FIGS. 8A and 8B is better defined than the corresponding shape of the checkerboard in FIGS. 7A and 7B. Additionally, the edges around the squares are sharper. For the brain images 721, 821 in FIGS. 7C and 8C or the brain images 771, 871 in FIGS. 7D and 8D, the difference in image quality may be observed, if at all, only at the faint skull structure around the brain. However, the phase-shift maps used in FIG. 8 were derived from four additional scans. In contrast, the phase-shift maps used in FIG. 7 were from the PLUS technique and needed no additional scans.

The system and method of the present invention employs phase labeling using sensitivity encoding (PLUS) to correct geometric distortion in EPI without using extra scans to map field inhomogeneity and coil sensitivity. The system and method of the present invention modifies a regular EPI trajectory and utilizes parallel imaging to create multiple images that are later used to reconstruct phase-shift maps for distortion correction. Since the phase-shift maps and the coil sensitivity are derived from the EPI measurements themselves, the method of the present invention eliminates problem arising from patient position inconsistencies between field mapping and coil sensitivity scans and the EPI measurements. In addition, with the method of the present invention, no interpolation is required since voxel positions and geometric distortions in the phase-shift maps, the coil sensitivity maps, and the measurements are similar. Therefore, the method of the present invention enables self-sufficient geometric correction of each dynamic point. Furthermore, the phase labeling using sensitivity encoding (PLUS) techniques of the present invention may be applied to both spin-echo and gradient-echo images.

As outlined, the method of the present invention eliminates ghosting artifacts by alternately assigning k-space lines that are scanned in the same direction into groups. The unfolded image from each group is free from ghosting artifacts and their interferences on the object under study. The average of the unfolded image is comparable to the image that is acquired using a regular EPI trajectory. In fact, this averaged unfolded image has a signal-to-noise ratio (SNR) equal to 1/g_{ρ} of the SNR of the image with a full FOV, where g_{ρ} is a geometry factor (g factor) at a pixel position ρ and it is greater than or equal to 1. For a reduction factor of four, the image folds four times, and pixels around the center of the image have the lowest SNR because the object (not including the background) superimposes many times. To increase SNR, images may also be acquired with a larger FOV.

In addition to the manner in which the EPI trajectories for phase labeling using sensitivity encoding were created described above, EPI trajectories for PLUS techniques may be created in many ways. For example, in FIGS. 10A and 10B, two additional EPI trajectories 1010, 1020 are shown.

The k-space lines in FIGS. 10A and 10B may be rearranged into 2 and 3 groups, respectively, according to the line order and direction shown as line styles (thick solid, thick dashed, and thick dash-dot lines). For example, in FIG. 10A, lines L11, L31, L51, L71 would be grouped together, and lines L21, L41, L61, L81 would be grouped together. Likewise, in FIG. 10B, lines L111, L411, L711 would be grouped together, lines L211, L511 would be grouped together, and lines L311, L611 would be grouped together. These groups create images that are folded 2 and 3 times, respectively, according to the number of groups. In FIG. 10A, the images after unfolding will be equivalent to the images with 0 blips added into the pre-phase-encoding gradient for the group L11, L31, L51, L71 and −2 additional blips added into the pre-phase-encoding gradient for the group L21, L41, L61, L81. In contrast, in FIG. 10B, the images after unfolding will be equivalent to the images with 0 blips added into the pre-phase-encoding gradient for the group L111, L411, L711, and −1 blips added into the pre-phase-encoding gradient for the group L311, L611, and +1 additional blips for the group L211, L511, respectively.

The phase labeling using sensitivity encoding (PLUS) techniques of the present invention eliminate phase errors by reading trajectory lines in the same direction. The alternative EPI trajectories illustrated in FIG. 10A includes lines L11, L31, L51, L71 in one group that were read from left to right and lines L21, L41, L61, L81 in the other group were read from right to left. So, although the numbers of folds for the trajectories in FIGS. 10A and 10 B are less than that of the trajectory in FIG. 1, these trajectories have less potential for improvements using PLUS techniques. The phases accumulated along the readout direction will not be canceled out when calculating the phase differences. As a consequence, the phase-shift map will likely contain positive and negative phase errors on the left and the right sides of the map.

Similarly, in FIG. 10B, each group contains k-space lines that were read in both directions. Therefore, ghosting artifacts may not be eliminated, resulting in a noisier phase-shift map. Therefore, additional ghosting artifact suppression techniques may improve the measurement accuracy when alternative trajectory lines are employed. The alternative trajectory lines shown in FIGS. 10A and 10B scan k-space without backtracking as in previous work. Other alternative trajectories may be employed with the system and method of the present invention as well, depending upon the object under study, the type of acquisition performed, and the scan parameters chosen. If backtracking the k-space is employed, however, this may reduce the efficiency of the acquisition.

To highlight the advantages of the phase labeling using sensitivity encoding (PLUS) techniques of the present invention, imaging sequences may use parallel imaging with a reduction factor less than or equal to one. Since the PLUS techniques utilize parallel imaging with a high reduction factor, the product of the reduction factors will ensure that the parallel imaging limit is not exceeded. That is, the number of coils or the noise level in the images will be sufficient for accurate phase-shift calculations.

Also, the signal-to-noise ratio (SNR) of the images after distortion correction is limited by geometry factors described above. Even though the image resolution in the final PLUS images is comparable to the typical resolution used in the field, to efficiently employ PLUS techniques, a larger field-of-view (FOV) may be recommended.

Further, to most effectively perform phase labeling using sensitivity encoding (PLUS) techniques of the present invention, strong blip gradients may be used. These stronger blip gradients may also increase the eddy current distortion in the image, so eddy-current compensation should be properly calibrated.

The present invention presents a significant advancement over previous geometric distortion correction techniques by removing the need for extra field map scans. By incorporating local phase shifts derived directly from the measurement itself, without the need of extra field map scans, the EPI scans and other fast MRI scans in accordance with the present invention maximize the benefit of shortened scan times while reducing artifacts.

The foregoing description of the present invention provides illustration and description, but is not intended to be exhaustive or to limit the invention to the precise one disclosed. Modifications and variations are possible consistent with the above teachings or may be acquired from practice of the invention. As such, the scope of the invention is defined by the claims and their equivalents.

1. A method of correcting geometric distortion in magnetic resonance imaging (MRI) images with phase labeling using sensitivity encoding, the method comprising:
providing an MRI system, said system producing a magnetic field
introducing an examination subject to the magnetic field;
transmitting radio frequency electromagnetic pulses to the examination subject with a radio frequency pulse generator;
applying magnetic field gradient pulses with a gradient amplifier following each of the radio frequency electromagnetic pulses;
collecting magnetic resonant signals from the examination subject using a phased array coil upon the examination subject receiving the transmitted radio frequency electromagnetic pulses and the applied magnetic field gradient pulses;
generating a k-space map based upon the magnetic resonant signals with a spectrometer;
performing a Fourier transformation on the generated k-space map to generate images from the phased array coil;
calculating a coil sensitivity measurement based upon the generated images and the phased array coil using a spectrometer processor;
generating a coil sensitivity map based upon the calculated coil sensitivity measurement;
rearranging the k-space map with interleaved trajectory lines;
generating unfolded images with different k-space shifts based upon the coils sensitivity map and the rearranged k-space map;
calculating the phase difference in the unfolded images to generate a phase shift map;
calculating an averaged unfolded image;
applying the phase shift map to the averaged unfolded image to correct the geometric distortion in the images.

2. The method according to claim 1, wherein rearranging the k-space map with interleaved trajectory lines includes:
rearranging k-space data into a number of groups;
alternately assigning a k-space trajectory line to each of the number of groups.

3. The method according to claim 2 further comprising:
filling missing k-space trajectory lines in each group with parallel imaging reconstruction data.

4. The method according to claim 1, wherein calculating the phase difference in the unfolded images to generate a phase shift map includes scanning the k-space trajectory lines in the same direction.

5. The method according to claim 1, further comprising:
up-sampling the image to reduce k-space aliasing artifacts prior to applying the phase shift map to the averaged unfolded image to correct the geometric distortion in the images.

6. The method according to claim 5, further comprising:
applying an inverse Fourier transformation to the image in a k_{y} direction; and
down-sampling the image to reduce the number of pixels to match an original image matrix size.

7. A magnetic resonance imaging system for correcting geometric distortion in magnetic resonance imaging (MRI) images with phase labeling using sensitivity encoding, the magnetic resonance imaging system comprising:
at least one magnetic coil producing a magnetic field;
a radio frequency pulse generator that transmits radio frequency electromagnetic pulses to an examination subject;
a gradient amplifier that applies magnetic field gradient pulses following each of the radio frequency electromagnetic pulses;
a radio frequency coil that collects magnetic resonant signals from the examination subject upon the examination subject receiving the transmitted radio frequency electromagnetic pulses and the applied magnetic field gradient pulses;
a spectrometer configured to generate a k-space map based upon the magnetic resonant signals and further configured to perform a Fourier transformation on the generated k-space map to generate images from radio frequency coil;
a spectrometer processor configured to calculate a coil sensitivity measurement based upon the generated images and the phased array coil and further configured to generate a coil sensitivity map based upon the calculated coil sensitivity measurement, rearrange the k-space map with interleaved trajectory lines, generate unfolded images with different k-space shifts based upon the coil sensitivity map and the rearranged k-space map, calculate the phase difference in the unfolded images to generate a phase shift map, calculate an averaged unfolded image, and apply the phase shift map to the averaged unfolded image to correct the geometric distortion in the images.

8. The system according to claim 7, wherein the spectrometer processor is further configured to rearrange the k-space map with interleaved trajectory lines by rearranging k-space data into a number of groups, and alternately assigning a k-space trajectory line to each of the number of groups.

9. The system according to claim 8, wherein the spectrometer is further configured to fill missing k-space trajectory lines in each group with parallel imaging reconstruction data.

10. The system according to claim 7, wherein the spectrometer processor is further configured to calculate the phase difference in the unfolded images to generate a phase shift map by scanning the k-space trajectory lines in the same direction.

11. The system according to claim 7, wherein the spectrometer processor is further configured to up-sample the image to reduce k-space aliasing artifacts prior to applying the phase shift map to the averaged unfolded image to correct the geometric distortion in the images.

12. The system according to claim 11, wherein the spectrometer processor is further configured to apply an inverse Fourier transformation to the image in a k_{y} direction and down-sample the image to reduce the number of pixels to match an original image matrix size.

13. A computer-readable medium having computer-executable instructions recorded thereon for correcting geometric distortion in magnetic resonance imaging (MRI) images with phase labeling using sensitivity encoding, the computer-executable instructions, when executed, causing a computer based system to perform the method of:
generating a k-space map based upon magnetic resonance imaging signals;
performing a Fourier transformation on the generated k-space map to generate viewable images;
calculating a coil sensitivity measurement based upon the generated images;
generating a coil sensitivity map based upon the calculated coil sensitivity measurement;
rearranging the k-space map with interleaved trajectory lines;
generating unfolded images with different k-space shifts based upon the coil sensitivity map and the rearranged k-space map;
calculating the phase difference in the unfolded images to generate a phase shift map;
calculating an averaged unfolded image;
applying the phase shift map to the averaged unfolded image to correct the geometric distortion in the images.

14. The computer-readable media according to claim 13, wherein rearranging the k-space map with interleaved trajectory lines includes:
rearranging k-space data into a number of groups;
alternately assigning a k-space trajectory line to each of the number of groups.

15. The computer-readable media according to claim 14 further comprising:
computer-executable instructions, when executed, cause the computer-based system to perform the method that includes filling missing k-space trajectory lines in each group with parallel imaging reconstruction data.

16. The computer-readable media according to claim 13, wherein calculating the phase difference in the unfolded images to generate a phase shift map includes scanning the k-space trajectory lines in the same direction.

17. The computer-readable media according to claim 13, further comprising:
computer-executable instructions, when executed, cause the system to perform the method that includes up-sampling the image to reduce k-space aliasing artifacts prior to applying the phase shift map to the averaged unfolded image to correct the geometric distortion in the images.

18. The computer-readable media according to claim 17, further comprising:
computer-executable instructions, when executed, cause the system to perform the method that includes applying an inverse Fourier transformation to the image in a k_{y} direction and
computer-executable instructions, when executed, cause a system to perform the method that includes down-sampling the image to reduce the number of pixels to match an original image matrix size.
